(19) United States
(12) Patent Application Publication
(10) Pub. No.: US 2025/0054759 A1
(43) Pub. Date: Feb. 13, 2025

(54) METAL OXIDE RESIST LAYERS INCLUDING BISMUTH AND PHOSPHORUS AND RELATED METHODS

(71) Applicant: Intel Corporation, Santa Clara, CA (US)

(72) Inventors: Charles Cameron Mokhtarzadeh, Portland, OR (US); Scott Peter Semproni, Fair Lawn, NJ (US); Scott B. Clendenning, Portland, OR (US)

(73) Assignee: Intel Corporation, Santa Clara, CA (US)

(21) Appl. No.: 18/932,266

(22) Filed: Oct. 30, 2024

(51) Int. Cl. H01L 21/033; G03F 7/004; G03F 7/16

(52) U.S. Cl. CPC H01L 21/0332; G03F 7/0043; G03F 7/162; G03F 7/167

(57) ABSTRACT

Metal oxide resist layers including bismuth and phosphorus, and related methods are disclosed herein. An example method of fabricating a semiconductor device, the method including depositing a metal oxide resist layer on a base material by applying a precursor including bismuth, the metal oxide resist layer including a bismuth phosphate compound and patterning the metal oxide resist layer.

### BACKGROUND

Semiconductor device fabrication includes various processes to manufacture integrated circuits or chips. Many processes involved in semiconductor device fabrication employ photolithography. Photolithography involves the application of light onto a layer of light-sensitive material (e.g., photoresist, also sometimes referred to simply as a resist) in a controlled manner to produce a pattern in the layer of material in which portions of the layer of material are retained while other portions are removed. Often, the exposure of light onto a photoresist is controlled through the use of a photolithography mask (e.g., a photomask or simply mask, etc.).

### BRIEF DESCRIPTION OF THE DRAWINGS

FIG. 1 illustrates an example system that includes a photomask to photolithographically pattern materials in an integrated circuit (IC) package and a metal oxide resist layer implemented in accordance with teachings of this disclosure.

FIG. 2A is a schematic diagram of the metal oxide resist layer of FIG. 1 including a plurality of bismuth-phosphorus compounds.

FIG. 2B is a chemical diagram of an example bismuth-phosphorus cluster morphology associated with the bismuth-phosphorous clusters of FIG. 2A.

FIG. 2C is a chemical diagram of an example bismuth-phosphorus coordination polymer morphology associated with the bismuth-phosphorus compounds of FIG. 2A.

FIG. 3 is a diagram depicting an example process for depositing the metal oxide resist layer of FIG. 2A via spin-on coating.

FIG. 4 is a diagram of example precursors that can be used in the process of FIG. 3.

FIG. 5 is a diagram depicting a plurality of example chemical reactions associated with the process of FIG. 3.

FIG. 6A is a diagram depicting an example process for depositing the metal oxide resist layer of FIG. 2A via atomic layer deposition.

FIG. 6B is a diagram depicting an example process for depositing the metal oxide resist layer of FIG. 2A via chemical vapor deposition.

FIG. 7 is a diagram of example precursors that can be used in the process of FIGS. 6A and 6B.

FIG. 8 is a diagram depicting a plurality of example chemical reactions associated with the processes of FIGS. 6A and 6B.

FIGS. 9A, 9B, and 9C are example tables including example reactive groups that can be used in conjunction with the compounds of FIGS. 2A-8.

FIG. 10 is a block diagram for example operations for depositing and patterning the resist layer of FIGS. 1 and 2A.

In general, the same reference numbers will be used throughout the drawing(s) and accompanying written description to refer to the same or like parts. The figures are not necessarily to scale. Instead, the thickness of the layers or regions may be enlarged in the drawings. Although the figures show layers and regions with clean lines and boundaries, some, or all of these lines and/or boundaries may be idealized. In reality, the boundaries and/or lines may be unobservable, blended, and/or irregular.

### DETAILED DESCRIPTION

In recent years, low-wavelength ultraviolet (UV) light has been used in photolithographic processes associated with semiconductor fabrication. Generally, lower wavelengths of UV light facilitate smaller features to be patterned on semiconductors, which enables the miniaturization thereof. Extreme ultraviolet lithographic techniques utilize UV radiation with wavelengths of less than 13.5 nanometers (nm). High numerical aperture extreme ultraviolet (High NA EUV) lithography utilizes UV radiation with wavelengths of approximately 8 nm. Such photolithographic techniques enable the production of semiconductor components with significantly higher densities than prior photolithographic techniques.

The use of UV light of such wavelengths requires the use of highly photo-sensitive stable materials due to the power demands of generating concentrated doses of such extreme ultraviolet light. One such class of highly photo-sensitive materials is metal oxides, which can be used as metal oxide resist (MOR) layers in negative tone photolithographic processes. When exposed to UV light, MOR layers crosslink (e.g., agglomerate, etc.), which increases the strength of the crosslinked portions of the MOR layer. After exposure, the unexposed portion is removed, and the underlying material is patterned. Prior MOR materials, such as Tin-oxide materials, exhibit low stability in atmospheric conditions, which can cause the MOR layer to degrade before patterning. Degradation of the resist layer increases the EUV light exposure intensity and/or duration required in the pattern process, which increases the power requirements of the EUV source and/or the total flux of EUV light. Some current MOR materials are deposited with additives to increase the stability of the MOR material. However, the use of such additives can decrease the density of the MOR layer. This decreased density can decrease the photosensitivity of the MOR layer, which increases the EUV dose required to pattern the resist layer and the underlying base material. Additionally, the minimum deposition thickness of prior MOR materials is unsuitable for high NA EUV lithography.

Examples disclosed herein address one or more of the deficiencies disclosed above. Some such examples include metal oxide resist materials that include bismuth-phosphorus compounds that are highly photo-sensitive, suitable for use in High NA EUV lithography processes, and atmospherically stable. Some example metal oxide resist layers disclosed herein include bismuth-14 phosphorus clusters. Other example metal oxide resist layers disclosed herein include a one-dimensional bismuth-phosphorus coordination polymer. Some example bismuth-phosphorus compounds disclosed herein include aromatic compounds, which have low reactivity with the ambient environment.

Example metal oxide resist layers disclosed herein can be synthesized via a bismuth-containing precursor and a phosphorus-containing precursor. In some such examples disclosed herein, the bismuth-containing precursor is a bismuth alkoxide. In other such examples disclosed herein, the bismuth-containing precursor is triphenylbismuthine. In some examples, the phosphorus-containing precursor is a phosphate and/or a phosphonate. The example precursors disclosed herein can be synthesized to include a variety of alkyl groups, which enable the selection of different bismuth-phosphorus compounds based on the application, desired reactivity, and/or conditions of the fabrication environment. For example, the precursors can be selected based on a desired density and/or a desired photosensitivity of the metal oxide resist layer. Example metal oxide resist materials disclosed herein can be deposited via atomic layer deposition (ALD), chemical vapor deposition (CVD), and/or spin-on deposition. Example metal oxide resist layers disclosed herein are atmospherically stable due to the absence of dangling reactive groups, such as hydroxyl (—OH), and are highly photo-sensitive due to the large EUV absorption cross section of bismuth.

Examples disclosed herein include references to chemical formulas and chemical equations. Generally, chemical formulas are referred to in their empirical forms (e.g., not their molecular form, etc.). Generally, elements in such chemical formulas and chemical equations are referred to herein by their chemical symbols (e.g., bismuth is referred to herein as “Bi,” carbon is referred herein to as “C,” hydrogen is referred to as “H,” etc.). In the accompanying drawings, molecules are depicted via organic chemistry conventions (e.g., carbon atoms are unlabeled, etc.). Additionally, alkyl groups are referred to as “R” (e.g., a chemical formula including “R” could include any alkyl group, etc.). Aromatic groups (e.g., groups containing a six-sided cyclically conjugated ring typified by benzene (C₆H₆), etc.) are referred to as “Ar.” Methyl groups (CH₃) are referred to as “Me.” Ethyl groups (CH₂CH₃) are referred to as “Et.” Butyl groups (C₄H₉) are referred to as “Bu.” Phenyl groups (C₆H₅) are referred to as “Ph.” Trimethylsilyl groups (C₃H₉Si) are referred to as “TMS.” Ligands that include trimethylsilyl (TMS) groups are referred to herein as a “silylated” and/or with the prefix “silyl-” (e.g., a phosphate including a TMS group is referred to herein as a silylated phosphate and a silyl-phosphate, etc.).

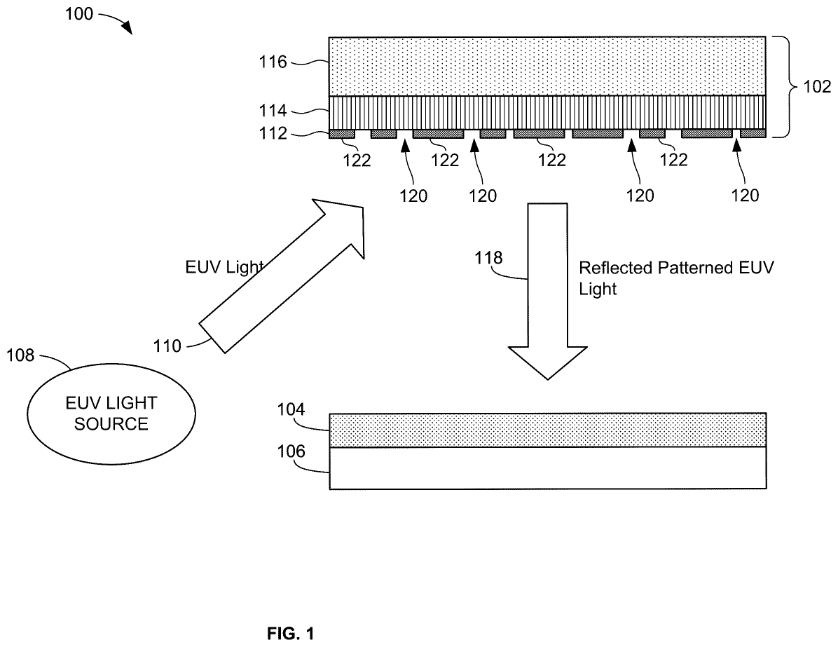

FIG. 1 illustrates an example system 100 that includes an example photomask 102 to photolithographically pattern a photoresist 104 on an underlying layer or substrate 106. In some examples, the underlying substrate 106 corresponds to a portion of an integrated circuit (IC) package. More particularly, in some instances, the underlying substrate 106 corresponds to a particular layer within a semiconductor die (e.g., an IC chip, etc.) within the IC package, a particular layer to be included within a package substrate for the IC package, and/or any other suitable substrate for an electronic device. In some instances, the photoresist 104 is patterned to define openings in the photoresist 104 that can then be used as a mask to create corresponding openings in the underlying substrate 106 (e.g., through an etching process that removes portions of the underlying substrate exposed through the openings in the photoresist 104). In some instances, instead of removing portions of the underlying substrate 106 exposed through the openings in the photoresist 104, the openings in the photoresist 104 can be filled with a material to be added onto the underlying substrate 106 at the locations defined by the openings. In some instances, the photoresist 104 is removed after subsequent processing associated with the use of the patterned openings have been completed. In other instances, the photoresist 104 is retained on the underlying substrate 106 and remains as part of the final product (e.g., some portion of an IC package).

The system 100 of FIG. 1 is an extreme ultraviolet (EUV) lithography system. Accordingly, as shown in FIG. 1, the system 100 includes an EUV light source 108 that produces EUV light 110. More particularly, the EUV light source 108 can be a laser driven light source (e.g., based on tin plasma) that produces EUV light (e.g., ultraviolet light at a wavelength of approximately 13.5 nanometers (nm)). As shown in FIG. 1, the EUV light 110 is directed towards the photomask 102. The photomask 102 includes an absorber 112 (also referred to herein as an absorber layer) having a defined pattern on an outer surface of a multilayer 114 (also referred to herein as a multilayer region). The absorber 112 is an opaque material capable of absorbing the EUV light 110. The multilayer 114 is defined by a stack of thin films or layers of materials capable of reflecting the EUV light 110. As shown in FIG. 1, both the patterned absorber 112 and the multilayer 114 are carried by a support substrate 116. In some examples, the support substrate 116 is a solid piece of glass (e.g., a glass pane, panel, or sheet).

As the EUV light 110 reaches the photomask 102, the absorber 112 absorbs the EUV light 110. The reflective films within the multilayer 114 reflect at least a portion of the EUV light (referred to herein as reflected patterned EUV light 118) that passes through a pattern in the absorber 112. The reflected patterned EUV light 118 is defined by the pattern of the absorber 112. That is, as shown in FIG. 1, the pattern of the absorber 112 is defined by openings 120 between opaque regions 122 of the absorber 112. The opaque regions 122 absorb at least a portion of the EUV light 110 so that the absorbed portion of the EUV light 110 is not reflected toward the photoresist 104. The openings 120 expose portions of the underlying multilayer 114 and the exposed portions of the multilayer 114 will reflect at least a portion of the EUV light 110 (e.g., the reflected patterned EUV light 118) towards the photoresist 104.

In the illustrated example of FIG. 1, the photoresist 104 is a photo-sensitive metal oxide resist (MOR) layer. The portions of the photoresist 104 exposed to the reflected patterned EUV light 118 react to the light by changing one or more characteristics. In the illustrated example of FIG. 1, the system 100 is a negative tone lithography system. That is, portions of the photoresist 104 exposed to light will harden (e.g., a change of a characteristic, etc.) such that when a developer solution is applied to the photoresist 104, the portions that remain relatively soft (e.g., the portions not exposed to the light, etc.) are removed while the hardened portions remain (e.g. are not removed, etc.). In this manner, the pattern defined by the opaque regions 122 of the absorber 112 on the photomask 102 are transferred to the photoresist 104. In other examples, the portions of the photoresist 104 exposed to the patterned EUV light 118 are weakened (e.g., softened, etc.) such that, when a developer solution is applied the exposed portions of the photoresist 104 are removed. In this manner, the pattern defined by the openings 120 in the absorber 112 (e.g., the inverse of the pattern defined by the opaque regions 122) is transferred to the photoresist 104.

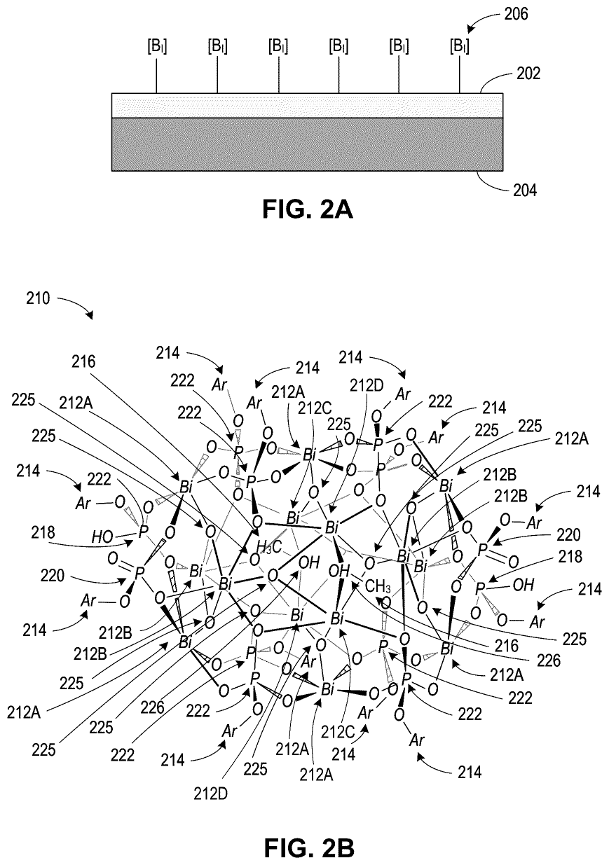

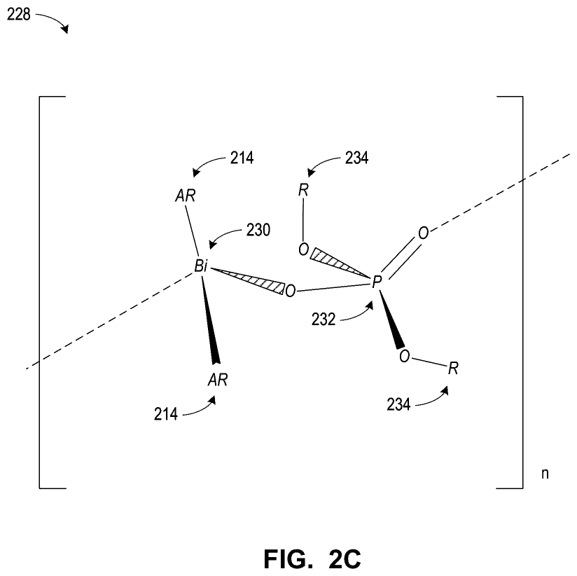

FIG. 2A is a schematic diagram of an example metal oxide resist layer 202 implemented in accordance with teachings of this disclosure. In the illustrated example of FIG. 2A, the metal oxide resist layer 202 is deposited on an example base layer 204. In some examples, the metal oxide resist layer 202 and the base layer 204 implement the photoresist 104 of FIG. 1 and the substrate 106 of FIG. 1, respectively. In the illustrated example of FIG. 2A, the metal oxide resist layer 202 includes an example plurality of bismuth-phosphorus compounds 206.

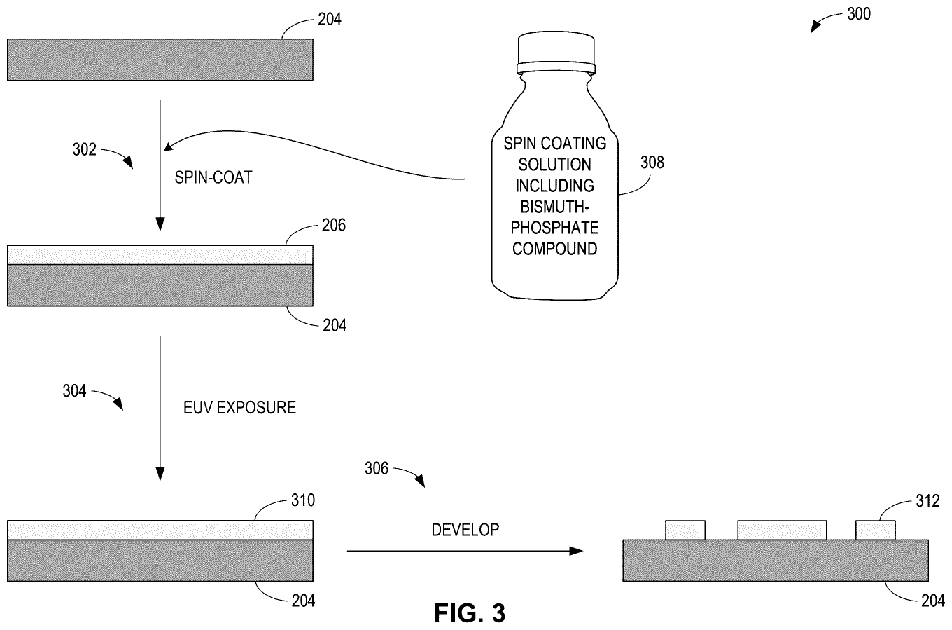

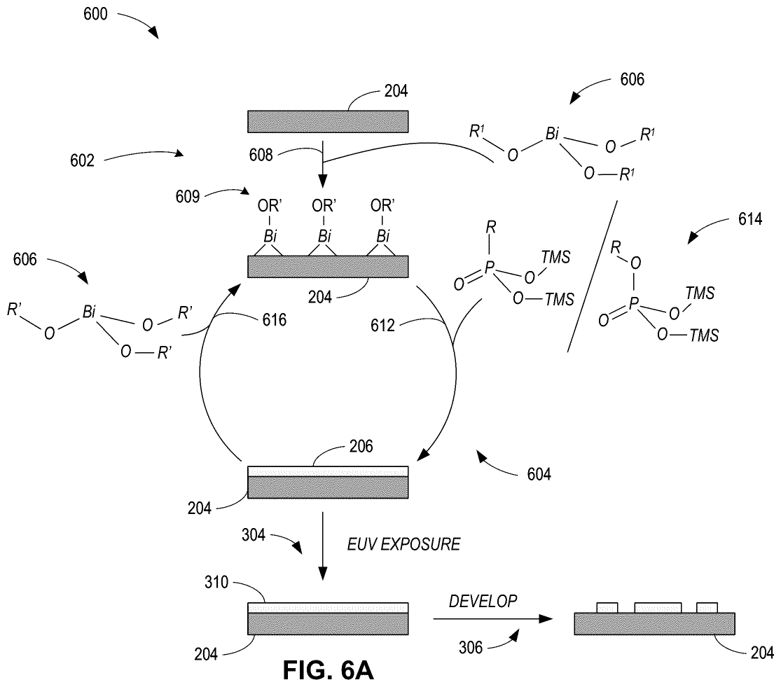

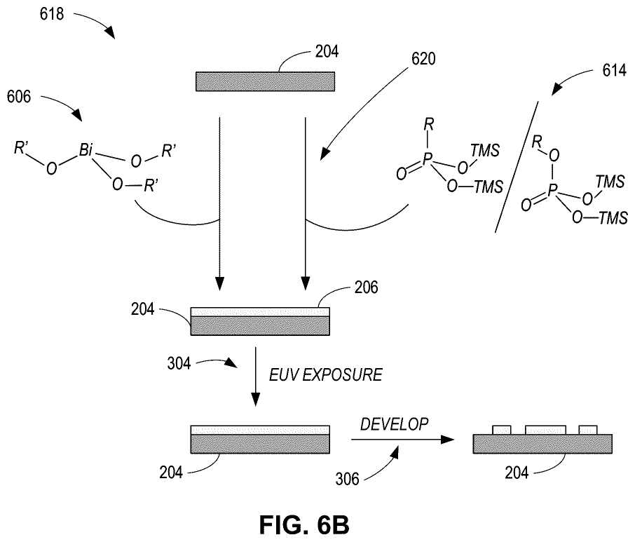

The metal oxide resist layer 202 of this example includes a plurality of the bismuth-phosphorus compounds 206. In some examples, the metal oxide resist layer 202 is applied via a spin-on technique. In some such examples, a solution containing the bismuth-phosphorus compounds 206 is applied to the base layer 204, and spread thereon by spinning the base layer 204 at a high speed. In some examples, the thickness of the metal oxide resist layer 202 can be controlled by the volume of the solution applied to the base layer 204. An example process diagram for depositing the metal oxide resist layer via spin-on coating is disclosed below in conjunction with FIG. 3. In some examples, the metal oxide resist layer 202 is deposited via atomic layer deposition (ALD). For example, the precursors for the bismuth-phosphorus compounds 206 can be alternatively pulsed into a reaction chamber including the base layer 204. In some such examples, the thickness of the metal oxide resist layer 202 can be controlled via the number of pulses of the precursors (e.g., each cycle of pulses of the precursors deposits a single molecule layer of the bismuth-phosphorus compounds 206, etc.). An example process diagram for depositing the metal oxide resist layer via atomic layer deposition is disclosed below in conjunction with FIG. 6A.

In other examples, the metal oxide resist layer 202 is deposited via chemical vapor deposition (CVD). For example, the precursors used to synthesize the bismuth-phosphorus compounds 206 can be applied concurrently (e.g., simultaneously, coflowed, etc.) to the base layer 204 as gases (e.g., as vapors, etc.). In some such examples, the thickness of the metal oxide resist layer 202 can be controlled by controlling via the length of the exposure to the precursors for the bismuth-phosphorus compounds 206 (e.g., a longer exposure time causes a thicker metal oxide resist layer than a shorter exposure time, etc.). An example process diagram for depositing the metal oxide resist layer via chemical vapor deposition is disclosed below in conjunction with FIG. 6B.

The base layer 204 of FIG. 2A is the material that is to be patterned via lithography. The base layer 204 is also referred to herein as the base material. In some examples, the base layer 204 is a semiconductor base layer that includes (e.g., is composed of, etc.) silicon dioxide (e.g., silica, SiO₂, etc.). In some examples, the base layer 204 is a component of an integrated circuit (e.g., a die, a package substrate, etc.) and/or another apparatus that includes extremely small components. Additionally or alternatively, the base layer 204 can include a metal (e.g., copper, aluminum, nickel, etc.). In some examples, after the removal of selected portions of the metal oxide resist layer 202 (e.g., via etching, etc.), the base layer 204 is patterned to form openings and/or holes in the base layer 204. In some examples, the openings created in the base layer 204 can have a resolution of less than 20 nm (e.g., based on the wavelength of the applied UV light, etc.). For example, the openings created in the base layer 204 can have a resolution of approximately 8 nanometers.

The bismuth-phosphorus compounds 206 are the base unit of the metal oxide resist layer 202. As used herein, the symbol [Bi] refers to the structure of the bismuth-phosphorus compounds 206 of the metal oxide resist layer 202. The bismuth-phosphorus compounds 206 are photo-sensitive molecules that crosslink when exposed to UV radiation. The bismuth-phosphorus compounds 206 are typified by the following chemical formula:

Bi_{w}O_{X}C_{Y}P_{Z} (1)
where Bi is bismuth, O is oxygen, C is carbon, and P is phosphorus, w is the number of bismuth atoms, x is the number of oxygen atoms, y is the number of carbon atoms, and z is the number of phosphorus atoms.

In the illustrated example of FIG. 2A, the bismuth-phosphorus compounds 206 have not been exposed to ultraviolet light. In some such examples, some of the bismuth-phosphorus compounds 206 may crosslink prior to exposure due to thermal crosslinking. In some examples, when the bismuth-phosphorus compounds 206 are exposed to ultraviolet light (e.g., EUV, etc.), adjacent ones of the bismuth-phosphorus compounds 206 can further aggregate and/or crosslink. That is, the application of UV light ionizes the bismuth-phosphorus compounds 206 and causes oxygens in the bismuth-phosphorus compounds 206 to bond with the bismuths of adjacent ones of the bismuth-phosphorus compounds 206. In some examples, the application of EUV light may cause the bond between the phosphorous atoms and carbon atoms in the bismuth-phosphorus compounds 206 to break, which can enable crosslinking between adjacent ones of the bismuth-phosphorus compounds 206 to occur. The crosslinking of the bismuth-phosphorus compounds 206 makes the exposed portions of the metal oxide resist layer 202 resistant to removal (e.g., via etching, etc.). As such, by selectively exposing portions of the metal oxide resist layer 202 to UV light (e.g., via the photomask 102 of FIG. 1, etc.), selective ones of the bismuth-phosphorus compounds 206 can be crosslinked, unexposed ones of the bismuth-phosphorus compounds 206 can be removed, and the metal oxide resist layer 202 can be patterned. In some such examples, the patterning of the metal oxide resist layer 202 enables the fabrication (e.g., patterning, selective deposition, etc.) of features on the base layer 204. Example bismuth-phosphorus morphologies and the crosslinking behavior (e.g., the aggregation modes, etc.) thereof that can implement the bismuth-phosphorous compounds 206 depicted below in FIG. 2B.

FIG. 2B is a chemical diagram of an example bismuth-phosphorus cluster morphology 210 that can implement the bismuth-phosphorus compounds 206 of FIG. 2A. In the illustrated example of FIG. 2B, the bismuth-phosphorus cluster morphology 210 includes example first bismuth atoms 212A, example second bismuth atoms 212B, example third bismuth atoms 212C, example fourth bismuth atoms 212D, twelve example aromatic groups 214, two example methyl groups 216, example first phosphate moieties 218, example second phosphate moieties 220, an example third phosphate moieties 222, example oxygen atoms 225, and two hydroxyl groups 226. In the illustrated example of FIG. 2B, the bismuth-phosphorus cluster morphology 210 includes fourteen bismuth atoms (e.g., 6 of the first bismuth atoms 212A, 4 of the second bismuth atoms 212B, 2 of the third bismuth atoms 212C, 2 of the fourth bismuth atoms 212D, etc.). That is, the bismuth-phosphorus cluster morphology 210 is a bismuth 14 cluster. It should be appreciated that the bismuth-phosphorus cluster morphology 210 is depicted as a skeletal structure and includes additional hydrogens and carbons that are not illustrated in the illustrated example of FIG. 2B in the interest of visual clarity.

The bismuth-phosphorus cluster morphology 210 has the following chemical formulas:

C₅H₁₇AR₁₂Bi₁₄O₅₉P₁₂ (2)

((ArO)PO₃)₁₀((ArO)PO(OH))₂(Bi₁₄O₁₀)·2(CH₃OH) (3)
where Bi is the bismuth (e.g., the bismuth atoms 212A, 212B, 212C, 212D, etc.), P is phosphorus (e.g., the phosphorus atoms of each of the phosphate moieties 218, 220, 222, etc.), O is oxygen (e.g., the oxygen atoms of the phosphate moieties 218, 220, 222 and the oxygen atoms 225, etc.), Me is the methyl groups 216, and AR is the aromatic groups 214. In some examples, the exact chemical composition of the bismuth-phosphorus cluster morphology 210 can vary up to 10% due to solvent co-crystallization during deposition of the bismuth-phosphorus cluster morphology 210.

In the illustrated example of FIG. 2B, each of the first bismuth atoms 212A has coordinate covalent bonds with four oxygens of the phosphate moieties 218, 220, 222, and one of the oxygen atoms 225 (e.g., each of the first bismuth atoms 212A has formed five bonds, each of the first bismuth atoms 212A is pentacoordinated, etc.). In the illustrated example of FIG. 2B, each of the second bismuth atoms 212B has coordinate covalent bonds with four oxygens of the phosphate moieties 218, 220, 222 and three of the oxygen atoms 225 (e.g., each of the second bismuth atoms 212B has formed seven bonds, each of the second bismuth atoms 212B is heptacoordinated, etc.). In the illustrated example of FIG. 2B, each of the third bismuth atoms 212C has coordinate covalent bonds with one oxygen of the third phosphate moieties 222, three of the oxygen atoms 225, and one oxygen of the hydroxyl groups 226 (e.g., each of the third bismuth atoms 212C has formed five bonds, each of the third bismuth atoms 212C is hexacoordinated, etc.). In the illustrated example of FIG. 2B, each of the fourth bismuth atoms 212D has coordinate covalent bonds with three oxygens of the phosphate moieties 218, 220, 222, three of the oxygen atoms 225, and one oxygen of the hydroxyl groups 226 (e.g., each of the fourth bismuth atoms 212C has formed seven bonds, each of the fourth bismuth atoms 212D is heptacoordinated, etc.). In other examples, some or all of the bismuth atoms 212A, 212B, 212C, 212D can have different bonding behavior based on the geometry of the bismuth-phosphorus cluster morphology 210 (e.g., based on the proximity of the bismuth atoms 212A, 212B, 212C, 212D to oxygens of the bismuth-phosphorus cluster morphology 210, etc.).

In the illustrated example of FIG. 2B, the first phosphate moieties 218 include an example phosphorus atom bonded to three oxygen atoms and an example hydroxyl group. In the illustrated example of FIG. 2B, the second phosphate moieties 220 include an example phosphorus atom single bonded to three oxygen atoms and double bonded to one oxygen atom. In the illustrated example of FIG. 2B, the third phosphate moieties 222 include an example phosphorus atom single bonded to four oxygen atoms. In the illustrated example of FIG. 2B, each of the phosphate moieties 218, 220, 222 is bonded to a corresponding ones of the aromatic groups 214. Example aromatic groups that can implement one or more of the aromatic groups 214 of FIG. 2 are disclosed below in conjunction with FIG. 6A.

The bismuth-phosphorus cluster morphology 210 is stable at room temperatures and degrades slowly in atmospheric conditions. Particularly, the bismuth-phosphorus cluster morphology 210 is kinetically stabilized to atmospherically induced decompositions pathways. Additionally, the bismuth-phosphorus cluster morphology 210 does not include metal-carbon bonds, which have comparatively higher sensitivity to atmospheric conditions (e.g., comparatively unstable, etc.) when compared to metal-oxygen bonds and are prone to facile homolysis. In some examples, when a cluster of the bismuth-phosphorus cluster morphology 210 is exposed to UV light (e.g., during EUV lithography, etc.), the phosphorous-carbon bonds of the cluster can break, which can enable the bismuth-phosphorus cluster morphology 210 to crosslink with one or more adjacent clusters of the bismuth-phosphorus cluster morphology 210. In some such examples, one or more of the first bismuth atoms 212A can form additional coordinate bonds with oxygens of the phosphate moieties 218, 220, 222. For example, one or more of the first bismuth atoms 212A can form covalent bonds with the hydroxyl groups of the first phosphate moieties 218. Additionally or alternatively, one or more of the first bismuth atoms 212A can form covalent bonds with the double-bonded oxygens of the second phosphate moieties 220 (e.g., causing the double-bonded oxygen to have a single covalent bond with the phosphorus of second phosphate moieties 220, etc.). The crosslinking of the bismuth-phosphorus cluster morphology 210 causes such crosslinked clusters to be resistant to removal during lithography processes. In other examples, the bismuth-phosphorus cluster morphology 210 can exhibit other crosslinking behavior.

FIG. 2C is a chemical diagram of an example bismuth-phosphorus coordination polymer morphology 228 that can implement the bismuth-phosphorus compounds 206 of FIG. 2A. In the illustrated example of FIG. 2C, the bismuth-phosphorus coordination polymer morphology 228 is a one-dimensional (1D) coordination polymer. In the illustrated example of FIG. 2C, the bismuth-phosphorus coordination polymer morphology 228 includes two of the aromatic groups 214, an example bismuth atom 230, an example phosphorus moiety 232, and two example alkyl groups 234. It should be appreciated that the molecule depicted in the illustrated example of FIG. 2C is a single unit of a repeating polymer. That is, the dashed lines in the illustrated example of FIG. 2C can be coupled to another unit of bismuth-phosphorus coordination polymer morphology 228.

The bismuth-phosphorus coordination polymer morphology 228 has the following chemical formula:

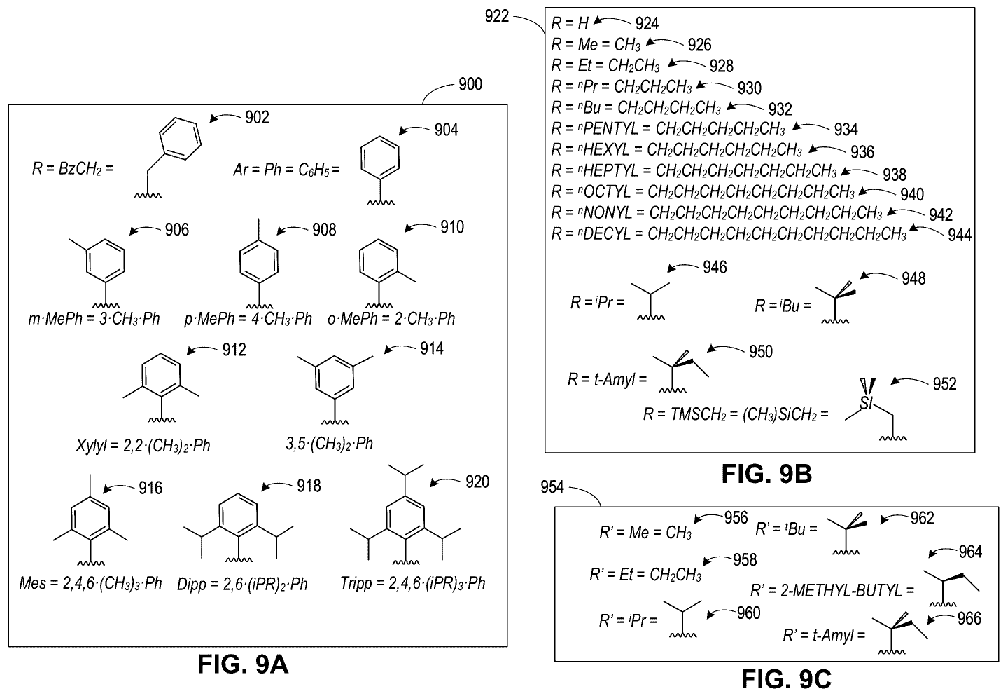

BiO₄PR₂ (4)
where Bi is the bismuth atom 230, P is the phosphorus atom of the phosphate moiety 232, O is the oxygen atoms of the phosphate moiety 232 and R is the alkyl groups 234. In the illustrated example of FIG. 2C, the bismuth atom 230 is coupled to the two alkyl groups 234, and an oxygen atom of the phosphate moiety 232. In some examples, the bismuth atom 230 is also coupled to an oxygen atom of an adjacent phosphorus moiety of the bismuth-phosphorus coordination polymer morphology 228. Example alkyl groups that can implement the alkyl group 234 of FIG. 2C are disclosed below in conjunction with FIG. 9B.

Like the bismuth-phosphorus cluster morphology 210 of FIG. 2A, the bismuth-phosphorus coordination polymer morphology 228 is stable at room temperatures and degrades slowly in atmospheric conditions. Additionally, bismuth atoms have a large EUV absorption cross-section and are one of the heaviest commercially available elements on the periodic table. The large atomic size and weight of bismuth causes many bismuth compounds, such as the bismuth-phosphorus cluster morphology 210 of FIG. 2B and the bismuth-phosphorus coordination polymer morphology 228 of FIG. 2C, to be highly photosensitive. Additionally, the high density of the bismuth-phosphorus cluster morphology 210 (i.e., ˜1.900 grams per cubic centimeter varying based on the aromatic groups 214, etc.) and the bismuth-phosphorus coordination polymer morphology 228 (i.e., ˜1.700 grams per cubic centimeter varying based on the alkyl groups 234, etc.) when compared to other MOR materials enables the bismuth-phosphorus cluster morphology 210 and the bismuth-phosphorus coordination polymer morphology 228 to be deposited in thinner layers than such prior MOR materials.

FIG. 3 is a diagram depicting an example first lithography process 300 for depositing the metal oxide resist layer 202 of FIG. 2A via spin-coating. In the illustrated example of FIG. 3, the first lithography process 300 includes example coating operations 302, example exposure operations 304, and example development operations 306. During the coating operation 302, an example solution 308 is deposited on the base layer 204 and spin-coated thereon. In some examples, the solution 308 is deposited on the base layer 204 as a liquid and the base layer 204 is rotated (e.g., spun, etc.) at high speeds until the solution 308 is evenly distributed thereon. In some examples, after the coating of the solution 308, the base layer 204 is cured (e.g., heat cured, light cured, etc.) until the solvent of the solution 308 has evaporated. The evaporation of the solvent leaves the metal oxide resist layer 202 on the base layer 204. In some examples, the thickness of the metal oxide resist layer 202 depends on the volume of the solution 308 applied, the viscosity and concentration of the solution 308, and the rotational velocity of the spin-coating associated with the coating operation 302.

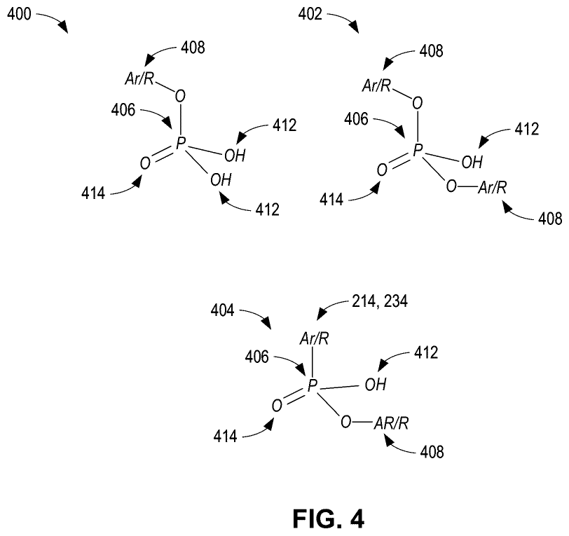

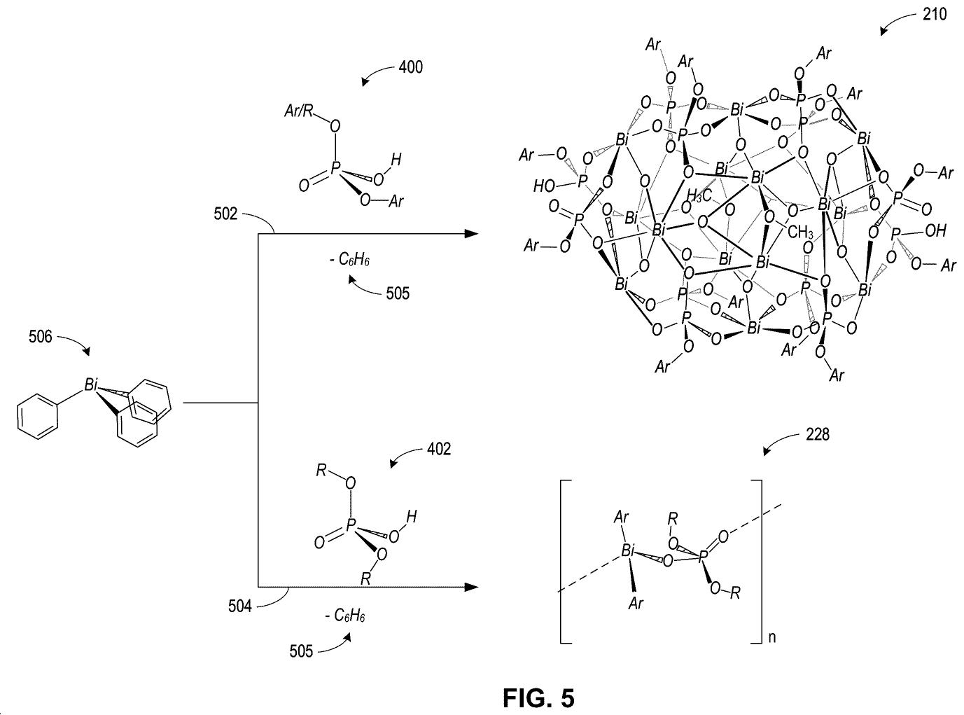

The solution 308 is a spin-coating solution that includes the bismuth-phosphorus compounds 206 of FIG. 2A dissolved in a solvent. For example, the bismuth-phosphorus cluster morphology 210 of FIG. 2B and/or the bismuth-phosphorus coordination polymer morphology 228 of FIG. 2C can be synthesized and dissolved into a solvent. Additionally or alternatively, the precursors for the bismuth-phosphorus compounds 206 can be dissolved in a solvent. In some such examples, the bismuth-phosphorus compounds 206 are synthesized via reactions in the solution 308. In other examples, the bismuth-phosphorus compounds 206 are formed after the exposure operations 304 (e.g., after the spin-coating of the solution 308, etc.). Example precursors to synthesize the bismuth-phosphorus compounds 206 for use in the first lithography process 300 are disclosed below in conjunction with FIGS. 4 and 5. In some examples, the solvent of the solution 308 is an organic solvent that includes one or more of 2-heptanone, anisole, propylene glycol monomethyl ether acetate (PGMEA), propylene glycol methyl ether (PGME), 1-Butanol, and/or toluene. In other examples, the solution 308 can include any other suitable solvents.

During the exposure operations 304, the metal oxide resist layer 202 is selectively exposed to UV light (e.g., EUV light, etc.). In the illustrated example of FIG. 3, the exposure of the metal oxide resist layer 202 to EUV light creates an example exposed metal oxide resist layer 310. The exposed oxide resist layer 310 includes crosslinked ones of the bismuth-phosphorus compounds 206, which causes the exposed portions of the exposed oxide resist layer 310 to be resistant to removal during the development operation 306. During the development operation 306, the unexposed portions of the exposed oxide resist layer 310 are removed to create an example patterned oxide resist layer 312. For example, the exposed oxide resist layer 310 can be exposed to a developer solution to remove the unexposed portions of the exposed oxide resist layer 310. After the development operations 306, the base layer 204 and the patterned oxide resist layer 312 can be patterned and/or otherwise processed via one or more semiconductor processing techniques (e.g., electroplating, vapor deposition, etching, etc.).

FIG. 4 is a diagram of an example first precursor 400, an example second precursor 402, and an example third precursor 404 that can be used in the first lithography process 300 of FIG. 3. That is, one or more of the precursors 400, 402, 404 can be reacted with a bismuth-containing precursor in a solution to generate the bismuth-phosphorus cluster morphology 210 of FIG. 2B and/or the bismuth-phosphorus coordination polymer morphology 228 of FIG. 2C.

The precursors 400, 402, 404 are phosphorus-containing precursors, which contain the atoms associated with the phosphate moieties 218, 220, 222 of the bismuth-phosphorus cluster morphology 210 of FIG. 2B and/or the phosphate moiety 232 of the bismuth-phosphorus coordination polymer morphology 228 of FIG. 2C. The first precursor 400 and the second precursor 402 are phosphates (e.g., the precursors 402, 404 are phosphate precursors, etc.). That is, the first precursor 400 and the second precursor 402 include an example central phosphorus atom 406, which is bonded to four oxygen atoms. In the illustrated example of FIG. 4, the central phosphorus atom 406 of the first precursor 400 is bonded to an example alkoxide group 408, two example hydroxyl groups 412, and is double bonded to an example oxygen atom 414. In the illustrated example of FIG. 4, the second precursor 402 is similar to the first precursor 400, except that central phosphorus atom 406 is bonded to two of the alkoxide groups 408 and one of the hydroxyl groups 412. The third precursor 404 is a phosphonate. In the illustrated example of FIG. 4, the third precursor 404 is similar to the second precursor 402, except that the central phosphorus atom 406 is directly bonded to the aromatic groups 214 of FIG. 2B or the alkyl group 234 of FIG. 2C. That is, the central phosphorus atom 406 of the third precursor 404 is bonded to three oxygens and a carbon and/or hydrogen of the aromatic groups 214 of FIG. 2B or the alkyl group 234.

FIG. 5 is a diagram depicting an example first chemical reaction 502 and an example second chemical reaction 504 associated with the first lithography process 300 of FIG. 3. In the illustrated example of FIG. 5, the chemical reactions 502, 504 generate an example byproduct 505. In the illustrated example of FIG. 5, the first chemical reaction 502 includes the reaction of an example bismuth-containing precursor 506 and the first precursor 400 of FIG. 4 to synthesize the bismuth-phosphorus cluster morphology 210 of FIG. 2B. The first chemical reaction 502 is depicted in Equation (5):

$$14 {Bi Ph}_{3} + 12 PO {( OH )}_{2} ArO + {H}_{2} O \to {( ( ArO ) {PO}_{3} )}_{10} {( ( ArO ) PO ( OH ) )}_{2} ( {Bi}_{14} {O}_{10} ) + 42 Bz \qquad ( 5 )$$

wherein BiPh₃ is the bismuth-containing precursor 506, PO(OH)₂ArO is the first precursor 400 of FIG. 4, ((ArO)PO₃)₁₀((ArO)PO(OH))₂(Bi₁₄O₁₀) is the bismuth-phosphorus cluster morphology 210 of FIG. 2B, H₂O is water, and Bz is benzene (e.g., the byproduct 505). In the illustrated example of FIG. 5, the bismuth-containing precursor 506 is triphenylbismuthine. In other examples, the bismuth-containing precursor 506 can be any other suitable molecule that includes bismuth. In the illustrated example of FIG. 5, the phosphorus-containing precursor is a phosphate (e.g., the first precursor 400, etc.). In other examples, the phosphorus-containing precursor is a phosphonate (e.g., a precursor similar to the third precursor 404 of FIG. 4, etc.). In the illustrated example of FIG. 5, the reaction of the bismuth-containing precursor 506 with a phosphorus-containing precursor including a single bonded aromatic group causes the formation of the bismuth-phosphorus cluster morphology 210 of FIG. 2B. In some examples, the first chemical reaction 502 can occur in the solution 308 of FIG. 3. In other examples, the first chemical reaction 502 can occur in a reaction chamber and/or a different solution.

In the illustrated example of FIG. 5, the second chemical reaction 504 includes the reaction of the bismuth-containing precursor 506 and the second precursor 402 of FIG. 4 to synthesize the bismuth-phosphorus coordination polymer morphology 228 of FIG. 2C. The second chemical reaction 504 is depicted in Equation (6):

$${Bi Ph}_{3} + PO {( O R )}_{2} OH \to {Bi Ph}_{2} {PO ( O R )}_{2} + Bz \qquad ( 6 )$$

wherein BiPh₃ is the bismuth-containing precursor 506, PO(OH)₂ArO is the second precursor 402 of FIG. 4, BiPh₂PO(OR)₂ is the bismuth-phosphorus coordination polymer morphology 228 of FIG. 2C, and Bz is benzene (e.g., the byproduct 505, etc.). In the illustrated example of FIG. 5, the phosphorus-containing precursor is a phosphate (e.g., the second precursor 402, etc.). In other examples, the phosphorus-containing precursor is a phosphonate (e.g., the third precursor 404 of FIG. 4, etc.). In the illustrated example of FIG. 5, the reaction of the bismuth-containing precursor 506 with a phosphorus-containing precursor including two bonded alkyl groups causes the formation of the bismuth-phosphorus coordination polymer morphology 228 of FIG. 2C. In some examples, the first chemical reaction 502 can occur in the solution 308 of FIG. 3. In other examples, the first chemical reaction 502 can occur in a reaction chamber and/or a different solution.

FIG. 6A is a diagram depicting an example second lithography process 600 for depositing the metal oxide resist layer of FIG. 2A via atomic layer deposition. In the illustrated example of FIG. 6A, the second lithography process 600 includes an example preliminary precursor pulse operation 602, an example precursor cycling operation 604, the exposure operations 304 of FIG. 3, and the development operations 306 of FIG. 3.

The preliminary precursor pulse operation 602 includes the application of an example bismuth-containing precursor 606 is applied to the base layer 204 of FIG. 2A via an example an example first pulse 608. In the illustrated example of FIG. 6A, the bismuth-containing precursor 606 is a bismuth alkoxide. In the illustrated example of FIG. 6A, the bismuth-containing precursor 606 includes a bismuth atom bonded to three alkoxide groups (e.g., ligands, etc.). In other examples, the bismuth-containing precursor 606 can be implemented by any other suitable substance including bismuth (e.g., the bismuth-containing precursor 506 of FIG. 5, etc.). In some examples, the bismuth-containing precursor 606 is synthesized within the chamber in which the second lithography process 600 occurs. In some such examples, a different compound including bismuth (e.g., triphenylbismuthine, etc.) can be pulsed into the chamber and react with substances (e.g., an alcohol, etc.) therein to form the bismuth-containing precursor 606 in situ. In some such examples, the bismuth-containing precursor 606 (e.g., a bismuth alkoxide, etc.). is a putative reactant. In some examples, the bismuth-containing precursor 606 is independently generated as a CVD precursor and re-introduced into the reaction chamber. Additionally or alternatively, the bismuth-containing precursor 606 can be pulsed directly onto the base layer 204.

The precursor cycling operation 604 causes a reaction between the bismuth-containing precursor 606 and reactive sites of the base layer 204. The first pulse 608 is represented via Equation (4):

$${Bi ( O R )}_{3} + 2 X \to {BiO RX}_{2}^{′} + 2 O RX \text{"} \qquad ( 3 )$$

where “Bi(OR)₃” is the bismuth-containing precursor 606, “2X” is the material as associated with the reactive sites of the base layer 204 (e.g., silicon, etc.), “BiORX′₂” is an example temporarily deposited material 609 deposited on the base layer 204 via the first pulse 608, and “20RX” is a byproduct of the first pulse 608. The identities of B′ and B″ depend on the material of the reactive sites of the base layer 204. In the illustrated example of FIG. 1, B′ is the portion of the material of the reactive sites of the base layer 204 that is associated with the byproduct of the reaction. For example, if the reactive sites of the base layer 204 are hydroxyls, the B′ is a hydrogen atom. In the illustrated example of FIG. 6A, B″ is the portion of the material of the reactive sites that forms a bond with the metal atom of the bismuth-containing precursor 606. For example, if the reactive sites are hydroxyls, the B″ is an oxygen atom.

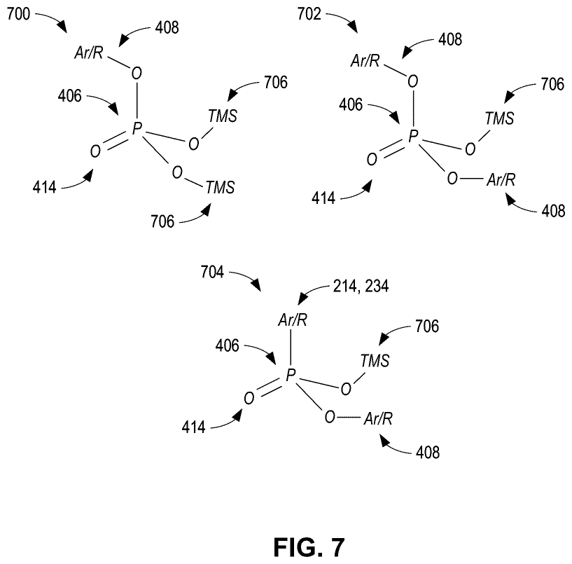

During the precursor cycling operation 604, an example second pulse 612 of an example phosphorus-containing precursor 614 and an example third pulse 616 of the bismuth-containing precursor 606 are applied to the base layer 202 to deposit the metal oxide resist layer 202. In the illustrated example of FIG. 6A, the phosphorus-containing precursor 614 includes an example a phosphorus atom bonded to an alkoxide group, an oxygen atom, and two TMS groups. Example precursors that can implement the phosphorus-containing precursor 614 are disclosed below in conjunction with FIG. 7.

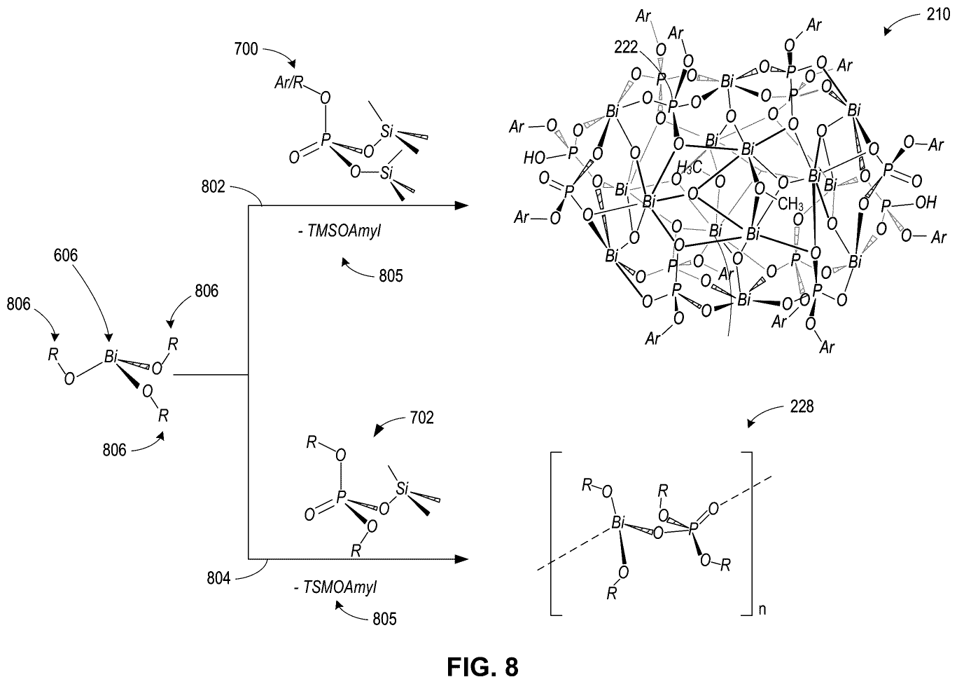

After the third pulse 616, a single molecule thick layer of the bismuth-phosphorus compounds 206 has been deposited on the base layer 204. The reaction between the bismuth-containing precursor 606 and the phosphorus-containing precursor 614 is disclosed below in additional detail in conjunction with FIG. 8. The reactive sites of the base layer (e.g., the exposed portions of the bismuth-phosphorus compounds 206, etc.) are similar to the temporarily deposited material 609. Accordingly, the precursor cycling operation 604 can be repeated (e.g., alternating between the second pulse 612 and the third pulse 616 to the metal oxide resist layer 202, etc.). In some examples, the thickness of the metal oxide resist layer 202 can be controlled via the number of application cycles of the pulses 612, 616 (e.g., each cycle of pulses applied increases the thickness of the metal oxide resist layer 202 by one molecule of the bismuth-phosphorus compounds 206, etc.).

The pulses 608, 612, 616 of the second lithography process 600 can be applied at temperatures of less than 250 degrees Celsius. In some such examples, temperatures of less than 250 degrees Celsius are favorable to formation of the bismuth-phosphorus compounds 206 (e.g., the bismuth-phosphorus cluster morphology 210 of FIG. 2A, the bismuth-phosphorus coordination polymer morphology 228 of FIG. 2B, etc.) and temperatures of greater than 250 degrees are favorable to the formation of bismuth-oxide and unfavorable to the bismuth-phosphorus compounds 206. In the illustrated example of FIG. 6A, after the precursor cycling operation 604 of FIG. 6A, the metal oxide resist layer 202 is processed by the exposure operations 304 of FIG. 3 and the development operations 306 of FIG. 3.

FIG. 6B is a diagram depicting an example third lithography process 618 for depositing the metal oxide resist layer of FIG. 2A via chemical vapor deposition. In the illustrated example of FIG. 6B, the third lithography process 618 includes the precursor flow operations 620, the exposure operations 304 of FIG. 3, and the development operations 306 of FIG. 3. During the precursor flow operations 620, the phosphorus-containing precursor 614 of FIG. 6A and the bismuth-containing precursor 606 of FIG. 6A are co-flowed as vapors onto the base layer 204. That is, the phosphorus-containing precursor 614 of FIG. 6A and the bismuth-containing precursor 606 of FIG. 6A are applied simultaneously to the base layer 204. In some examples, the thickness of the metal oxide resist layer 202 can be controlled via the length of the precursor flow operations 620 (e.g., increasing the length of the exposure to the phosphorus-containing precursor 614 of FIG. 6A and the bismuth-containing precursor 606 correspondingly increase the thickness of the metal oxide resist layer 202, etc.). In some examples, the precursor flow operations 620 of the third lithography process 618 can be applied at temperatures of less than 250 degrees Celsius. In the illustrated example of FIG. 6B, after the precursor flow operations 620 of FIG. 6B, the metal oxide resist layer 202 is processed by the exposure operations 304 of FIG. 3, and the development operations 306 of FIG. 3 to pattern the metal oxide resist layer 202 via lithography.

FIG. 7 is a diagram of an example first precursor 700, an example second precursor 702, and an example third precursor 704 that can implement the phosphorus-containing precursor 614 in the second lithography process 600 of FIG. 6A and the third lithography process 618 of FIG. 6B. That is, the precursors 700, 702, 704 can be reacted with a bismuth-containing precursor in a solution to generate the bismuth-phosphorus cluster morphology 210 of FIG. 2B and/or the bismuth-phosphorus coordination polymer morphology 228 of FIG. 2C via a vapor deposition process (e.g., chemical vapor deposition, atomic layer deposition, etc.). The precursors 700, 702, 704 are similar to the precursors 400, 402, 404 of FIG. 4, respectively, except as noted otherwise. That is, the first precursor 700 and the second precursor 702 are phosphates and the third precursor 704 is a phosphonate. In the illustrated example of FIG. 7, the first precursor 700 and the second precursor 702 include the central phosphorus atom 406 of FIG. 4, which is bonded to the example alkoxide group 408 of FIG. 4 and is double bonded to the oxygen atom 414. In the illustrated example of FIG. 4, the third precursor 704 includes the central phosphorus atom 406, which is directly bonded to the aromatic groups 214 of FIG. 2B or the alkyl group 234 of FIG. 2C and is double bonded to the oxygen atom 414.

Unlike the precursors 400, 402, 404 of FIG. 4, the precursors 700, 702, 704 are silylated. That is, instead of the hydroxyl groups 412 of FIG. 4, the central phosphorus atom 406 of precursors 700, 702, 704 is bonded to example TMS groups 706. In the illustrated example of FIG. 4, the first precursor 700 is bonded to two of the TMS groups 706, the second precursor 702 is bonded to one of the TMS groups 706, and the third precursor 704 is bonded to one of the TMS groups 706. The presence of the TMS groups 706 increases the volatility (e.g., reactiveness, etc.) of the precursors 700, 702, 704 when compared to the precursors 400, 402, 404 of FIG. 4, which makes the precursors 700, 702, 704 suitable for use in vapor deposition techniques.

FIG. 8 is a diagram depicting an example third chemical reaction 802 and an example fourth chemical reaction 804 associated with the lithography processes 600, 618 of FIGS. 6A and 6B. In the illustrated example of FIG. 8, the chemical reactions 802, 804 generate an example byproduct 805. In the illustrated example of FIG. 8, the third chemical reaction 802 includes the reaction of the bismuth-containing precursor 606 of FIG. 6A and the first precursor 700 of FIG. 7 to synthesize the bismuth-phosphorus cluster morphology 210 of FIG. 2B. The third chemical reaction 802 is depicted in Equation (7):

$$14 {Bi ( {O R}^{′} )}_{3} + 12 {PO ( TMS )}_{2} ArO \to {( ( ArO ) {PO}_{3} )}_{10} {( ( ArO ) PO ( OH ) )}_{2} ( {Bi}_{14} {O}_{10} ) \cdot 2 ( {CH}_{3} OH ) + TMSOAmyl \qquad ( 7 )$$

wherein Bi(OR′) is the bismuth-containing precursor 606, 12PO(TMS)₂ArO is the first precursor 700 of FIG. 7, ((ArO)PO₃)₁₀((ArO)PO(OH))₂(Bi₁₄O₁₀)·₂(CH₃OH) is the bismuth-phosphorus cluster morphology 210 of FIG. 2B, and TMSOAmyl is trimethylsilyl pentane. In the illustrated example, the phosphorus-containing precursor is a phosphate (e.g., the first precursor 700, etc.). In other examples, the phosphorus-containing precursor is a phosphonate (e.g., a precursor similar to the third precursor 704 of FIG. 7, etc.). In the illustrated example of FIG. 8, the reaction of the bismuth-containing precursor 606 with a phosphorus-containing precursor including a single bonded aromatic group causes the formation of the bismuth-phosphorus cluster morphology 210 of FIG. 2B. The third chemical reaction 802 is favorable at low-temperature vapor interactions of the bismuth-containing precursor 606 and the first precursor 700 of FIG. 7.

In the illustrated example of FIG. 8, the fourth chemical reaction 804 includes the reaction of the bismuth-containing precursor 606 and the second precursor 702 of FIG. 7 to synthesize the bismuth-phosphorus coordination polymer morphology 228 of FIG. 2C. The fourth chemical reaction 804 is depicted in Equation (5):

$${Bi ( {O R}^{′} )}_{3} + {POTMS ( O R )}_{2} \to {Bi ( {O R}^{′} )}_{2} {PO ( O R )}_{2} + TMSOAmyl \qquad ( 5 )$$

wherein Bi(OR′) is the bismuth-containing precursor 606, POTMS(OR)₂ is the second precursor 702 of FIG. 7, Bi(OR′)₂PO(OR)₂ is the bismuth-phosphorus coordination polymer morphology 228 of FIG. 2C, and TMSOAmyl is trimethylsilyl pentane. In the illustrated example of FIG. 8, the phosphorus-containing precursor is a phosphate (e.g., the second precursor 702, etc.). In other examples, the phosphorus-containing precursor is a phosphonate (e.g., the third precursor 704 of FIG. 7, etc.). In the illustrated example of FIG. 8, the reaction of the bismuth-containing precursor 606 with a phosphorus-containing precursor including two bonded alkyl groups causes the formation of the bismuth-phosphorus coordination polymer morphology 228 of FIG. 2C. The fourth chemical reaction 804 is favorable at low-temperature vapor interactions of the bismuth-containing precursor 606 and the second precursor 702 of FIG. 7.

FIG. 9A is an example first table 900 of example aromatic groups. The first table 900 of aromatic groups that can be used to implement the aromatic groups 214 of the bismuth-phosphorus cluster morphology 210 of FIG. 2B, the precursors 400, 402, 404 of FIG. 4, and/or the precursors 700, 702, 704 of FIG. 7. In the illustrated example of FIG. 9A, the first table 900 includes an example first aromatic 902, an example second aromatic 904, an example third aromatic 906, an example fourth aromatic 908, an example fifth aromatic 910, an example sixth aromatic 912, an example seventh aromatic 914, an example eighth aromatic 916, an example ninth aromatic 918, and an example tenth aromatic 920. In the illustrated example of FIG. 9A, the first aromatic 902 is a benzyl group. That is, the first aromatic 902 includes a benzene (Bz) bond to a vinyl group. In the illustrated example of FIG. 9A, the first aromatic 902 is labeled with “R” because the first aromatic 902 is bonded to metal via a vinyl. In the illustrated example of FIG. 9A, the second aromatic 904 is a phenyl group (e.g., a phenyl ring, etc.). In the illustrated example of FIG. 9A, the third aromatic 906 is m-toluene (e.g., meta-toluene, etc.). That is, the third aromatic 906 includes a phenyl group with a substituted methyl group that is separated from the parent compound by one carbon. In the illustrated example of FIG. 9A, the fourth aromatic 908 is p-toluene (e.g., para-toluene, etc.). That is, the fourth aromatic 908 includes a phenyl group with a substituted methyl group that is separated from the parent compound by two carbons (e.g., the substituted methyl group is opposite the parent compound, etc.). In the illustrated example of FIG. 9A, the fifth aromatic 910 is o-toluene (e.g., ortho-toluene, etc.). That is, the fifth aromatic 910 includes a phenyl group with a substituted methyl group that is adjacent to the parent compound.

In the illustrated example of FIG. 9A, the sixth aromatic 912 is a 2,6 xylyl group (e.g., a 2,6 dimethylphenol, a xylyl group with substitutions at the second carbon and six carbon of the phenyl rings, etc.). In the illustrated example of FIG. 9A, the seventh aromatic 914 is a 3,5 xylyl group (e.g., a 3,5 dimethylphenol, a xylyl group with substitutions at the third carbon and fifth carbon of the phenyl rings, etc.). In the illustrated example of FIG. 9A, the eighth aromatic 916 is a mesitylene group (e.g., a 2,4,6 trimethylphenol, a mesitylene group with substitutions at the second carbon, fourth carbon, and sixth carbon of the phenyl rings, etc.). In the illustrated example of FIG. 9A, the ninth aromatic 918 is a 2,6-diisopropylphenyl group (e.g., a diisopropylphenyl group with substitutions at the second carbon, and sixth carbon of the phenyl rings, etc.). In the illustrated example of FIG. 9A, the tenth aromatic 920 is a 2,4,6-trisopropylphenyl group (e.g., a trisopropylphenyl group with substitutions at the second carbon, fourth carbon, and sixth carbon of the phenyl rings, etc.). The aromatic groups 214 of FIGS. 2B, 4, and 8 can be implemented by a benzyl group (e.g., the first aromatic 902, etc.), a phenyl group (e.g., the second aromatic 904, etc.), an m-toluene group (e.g., the third aromatic 906, etc.), a p-toluene group (e.g., the fourth aromatic 908, etc.), an o-toluene group (e.g., the fifth aromatic 910, etc.), a 2,6 xylyl group (e.g., the sixth aromatic 912, etc.), a 3,5 xylyl group (e.g., the seventh aromatic 914, etc.), a mesitylene group (e.g., the eighth aromatic 916, etc.), a 2,6-diisopropylphenyl group (e.g., the ninth aromatic 918, etc.), or a 2,4,6-trisopropylphenyl group (e.g., the tenth aromatic 920, etc.). In other examples, the aromatic groups 214 of FIGS. 2B, 4, and 8 can be implemented by another suitable aromatic group.

FIG. 9B is an example second table 922 of example aromatic groups. The second table 922 of alkyl groups that can be used to implement the alkyl groups 234 of the bismuth-phosphorus cluster morphology 210 of FIG. 2C, the precursors 400, 402, 404 of FIG. 4, and/or the precursors 700, 702, 704 of FIG. 7. In the illustrated example of FIG. 9B, the first table 922 includes an example hydrogen 924 (e.g., a single hydrogen atom, etc.), an example first alkyl 926, an example second alkyl 928, an example third alkyl 930, an example fourth alkyl 932, an example fifth alkyl 934, an example sixth alkyl 936, an example seventh alkyl 938, an example eighth alkyl 940, an example ninth alkyl 942, an example tenth alkyl 944, an example eleventh alkyl 946, an example twelfth alkyl 948, an example thirteenth alkyl 950, and an example fourteenth alkyl 952. In the illustrated example of FIG. 9B, the first alkyl 926 is a methyl group. In the illustrated example of FIG. 9B, the second alkyl 928 is an ethyl group. In the illustrated example of FIG. 9B, the third alkyl 930 is an n-propyl group (e.g., a linear propyl group, etc.). In the illustrated example of FIG. 9B, the fourth alkyl 932 is an n-butyl group (e.g., a linear butyl group, etc.). In the illustrated example of FIG. 9B, the fifth alkyl 934 is an n-pentyl group (e.g., a linear pentyl group, etc.). In the illustrated example of FIG. 9B, the sixth alkyl 936 is an n-hexyl group (e.g., a linear hexyl group, etc.).

In the illustrated example of FIG. 9B, the seventh alkyl 938 is an n-heptyl group (e.g., a linear heptyl group, etc.). In the illustrated example of FIG. 9B, the eighth alkyl 940 is an n-octyl group (e.g., a linear heptyl group, etc.). In the illustrated example of FIG. 9B, the ninth alkyl 942 is an n-nonyl group (e.g., a linear nonyl group, etc.). In the illustrated example of FIG. 9B, the tenth alkyl 944 is an n-decyl group (e.g., a linear decyl group, etc.). In the illustrated example of FIG. 9B, the eleventh alkyl 946 is an isopropyl group. In the illustrated example of FIG. 9B, the twelfth alkyl 948 is a tert-butyl group. In the illustrated example of FIG. 9B, the thirteenth alkyl 950 is a tert-amyl group. In the illustrated example of FIG. 9B, the fourteenth alkyl 952 is trimethylsilyl group. The alkyl groups 234 of FIGS. 2C, 4, and 8 can be implemented by the hydrogen atom 924, a methyl group (e.g., the first alkyl 926, etc.), a ethyl group (e.g., the second alkyl 928, etc.), a n-propyl group (e.g., the third alkyl 930, etc.), a n-butyl group (e.g., the fourth alkyl 932, etc.), an n-pentyl group (e.g., the fifth alkyl 934, etc.), a n-hexyl (e.g., the sixth alkyl 936, etc.), a n-heptyl group (e.g., the seventh alkyl 938, etc.), a n-octyl group (e.g., the eighth alkyl 940, etc.), a n-nonyl group (e.g., the ninth alkyl 942, etc.), a n-decyl group (e.g., the tenth alkyl 944, etc.), an isopropyl group (e.g., the eleventh alkyl 946, etc.), a tert-butyl group (e.g., the twelfth alkyl 948, etc.), a tert-amyl group (e.g., the thirteenth alkyl 950, etc.), or a trimethylsilyl group (e.g., the fourteenth alkyl 952, etc.). In other examples, the alkyl groups 234 of FIGS. 2C, 4, and 8 can be implemented by another suitable alkyl group(s).

FIG. 9C is an example third table 954 of example alkyl groups. The third table 954 of alkyl groups that can be used to implement the alkyl groups 806 of the bismuth-containing precursor 606 of FIGS. 6A, 6B and 8. In the illustrated example of FIG. 9C, the third table 954 includes an example an example sixteenth alkyl 956, an example seventeenth alkyl 958, an example eighteenth alkyl 960, an example nineteenth alkyl 962, an example twentieth alkyl 964, and an example twenty-first alkyl 966. In the illustrated example of FIG. 9C, the sixteenth alkyl 956 is a methyl group. In the illustrated example of FIG. 9C, the seventeenth alkyl 958 is an ethyl group. In the illustrated example of FIG. 9C, the eighteenth alkyl 960 is an iso-propyl group. In the illustrated example of FIG. 9C, the nineteenth alkyl 962 is a tert-butyl group. In the illustrated example of FIG. 9C, the twentieth alkyl 964 is a 2-methyl-butyl group (e.g., a chain of two methyl groups coupled to a tert-butyl, etc.). In the illustrated example of FIG. 9C, the twenty-first alkyl 966 is a tert-amyl group. The alkyl groups 806 of the bismuth-containing precursor 606 of FIGS. 6A, 6B, and 8 can be implemented by a methyl group (e.g., the sixteenth alkyl 956, etc.), an ethyl group (e.g., the seventeenth alkyl 958, etc.), an iso-propyl group (e.g., the eighteenth alkyl 960, etc.), a tert-butyl group (e.g., the nineteenth alkyl 962, etc.), 2-methyl-butyl group (e.g., the twentieth alkyl 964, etc.), and a tert-amyl group (e.g., the twenty-first alkyl 966, etc.). In some examples, each of the alkyl groups 806 of the bismuth-containing precursor 606 can be implemented by different ones of the alkyls 956, 958, 960, 962, 964, 966. Additionally or alternatively, some or all of the alkyl groups 806 of FIG. 8 can be implemented by another suitable alkyl group(s).

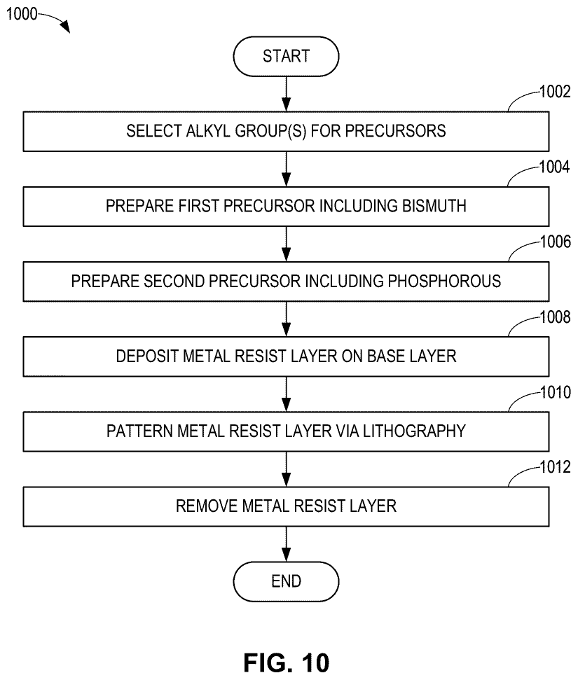

FIG. 10 is a block diagram for example operations 1000 for depositing and patterning the metal oxide resist layer 202 of FIGS. 1 and 2A including the bismuth-phosphorus compounds 206 such as the bismuth-phosphorus cluster morphology 210 of FIGS. 2B, 4, and 7 and the bismuth-phosphorus coordination polymer morphology 228 of FIGS. 2C, 4 and 7.

At block 1002, at which the alkyl group(s) for the preparation of the precursors are selected. For example, if the first chemical reaction 502 of FIG. 5 is to be used to synthesize the bismuth-phosphorus compounds 206, the aromatic groups 214 of FIG. 2B can be selected from among a group consisting of the aromatics 902-920 of the first table 900 of FIG. 9A. In some examples, if the second chemical reaction 504 of FIG. 5 is to be used to synthesize the bismuth-phosphorus compounds 206, the alkyl groups 234 of FIG. 2C can be selected from among a group consisting of the alkyls 924-952 of the second table 922 of FIG. 9B. In some examples, if the third chemical reaction 802 of FIG. 8 is to be used to synthesize the bismuth-phosphorus compounds 206, the aromatic groups 214 of FIG. 2B can be selected from among a group consisting of the aromatics 902-920 of the first table 900 of FIG. 9A and the alkyl groups 806 of the bismuth-containing precursor 606 of FIGS. 6A, 6B, and 8 can be selected from among a group consisting of the aromatics 902-920 of the third table 954 of FIG. 9C. In some examples, if the fourth chemical reaction 804 of FIG. 8 is to be used to synthesize the bismuth-phosphorus compounds 206, the alkyl groups 234 of FIG. 2C can be selected from among a group consisting of the alkyls 924-952 of the second table 922 of FIG. 9B and the alkyl groups 806 of the bismuth-containing precursor 606 of FIGS. 6A, 6B, and 8 can be selected from among a group consisting of the aromatics 902-920 of the third table 954 of FIG. 9C. In some examples, the alkyl group(s) for the synthesis of the precursors can be selected based on the desired density and photosensitivity of the deposited metal oxide resist layer 202.

At block 1004, a bismuth-containing precursor is prepared. For example, a bismuth-containing precursor can be prepared (e.g., synthesized, acquired, etc.) with a phenyl group and/or the alkyl group(s) selected during the execution of block 1002. In some examples, the bismuth-containing precursor 506 can be prepared (e.g., bismuth trialkioxide, etc.). In some examples, the bismuth-containing precursor 606 of FIG. 6 can be prepared (e.g., triphenylbismuthine, etc.). At block 1006, a phosphorus-containing precursor is prepared. For example, a phosphate precursor and/or a phosphonate precursor can be prepared (e.g., synthesized, acquired, etc.) with the alkyl group(s) selected during the execution of block 1002. In some examples, if a metal oxide resist layer 202 containing (e.g., primarily containing, only containing, etc.) the bismuth-phosphorus cluster morphology 210 is to be prepared, a phosphorus-containing precursor a single bonded alkyl group and/or aromatic group is selected (e.g., the first precursor 400 of FIG. 4, the first precursor 700 of FIG. 7, etc.). In some examples, if a metal oxide resist layer 202 containing (e.g., primarily containing, only containing, etc.) the bismuth-phosphorus coordination chain 222 is to be prepared, a phosphorus-containing precursor including two bonded alkyl groups and/or aromatic groups is selected (e.g., the second precursor 402 of FIG. 4, the third precursor 404 of FIG. 4, the second precursor 702 of FIG. 7, the third precursor 704 of FIG. 7, etc.). In some examples, if the metal oxide resist layer 202 is to be deposited via spin-on coating, a non-silylated phosphorus-containing precursor is prepared (e.g., one or more of the precursors 400, 402, 404 of FIG. 4, etc.). In other examples, if the metal oxide resist layer 202 is to be deposited via a vapor deposition process (e.g., ALD, CVD, etc.), a silylated phosphorus-containing precursor is prepared (e.g., one or more of the precursors 700, 702, 704 of FIG. 7, etc.).

At block 1008, the metal oxide resist layer 202 is deposited on the base layer 204. For example, the metal oxide resist layer 202 can be deposited via the first lithography process 300 of FIG. 3. For example, the bismuth-containing precursor prepared during the execution of block 1004, and the phosphorus-containing precursor prepared during the execution of block 1006 can be dissolved in a solution (e.g., the solution 308 of FIG. 3, etc.) and applied to the base layer 204 via spinning coating. In some such examples, the solution can be evaporated, which leaves the metal oxide resist layer 202 on the base layer 204. For example, the metal oxide resist layer 202 can be deposited via the third lithography process 618 of FIG. 6C. In other examples, the bismuth-containing precursor prepared during the execution of block 1004 and the phosphorus-containing precursor prepared during the execution of block 1006 are applied simultaneously as vapors on the base layer 204 via chemical vapor deposition. Additionally or alternatively, the metal oxide resist layer 202 can be deposited via the second lithography process 600 of FIG. 6A. For example, the bismuth-containing precursor prepared during the execution of block 1004 and the phosphorus-containing precursor prepared during the execution of block 1006 can be applied alternatively via vapor pulses via atomic layer deposition.

At block 1010, the metal oxide resist layer 202 is patterned. For example, the metal oxide resist layer 202 can be patterned via the operations 304, 306 of FIGS. 3, 6A, and 6B. In some such examples, the metal oxide resist layer 202 is exposed to ultraviolet light with a wavelength of less than 20 nanometers (e.g., 13.5 nanometers, etc.), which causes the crosslinking (e.g., polymerization, etc.) of the exposed portions of the metal oxide resist layer 202. In some examples, openings in the metal oxide resist layer 202 are created by etching (e.g., dry etching, wet etching, etc.) the metal oxide resist layer 202, which removes the non-crosslinked portions of the metal oxide resist layer 202. In some examples, the base layer 204 is patterned via semiconductor manufacturing techniques (e.g., ALD, CVD, electroplating, laser sintering, etc.). At block 1012, the metal resist layer is removed. For example, the metal oxide resist layer 202 can be mechanically removed (e.g., planarization, etching, etc.). The operations 1000 end.

Although the example operations 1000 are disclosed with reference to the flowchart illustrated in FIG. 10, many other methods of assembling an interconnect implemented in accordance with the teachings of this disclosure may alternatively be used. For example, the order of execution of the blocks may be changed, and/or some of the blocks disclosed may be changed, eliminated, or combined.

“Including” and “comprising” (and all forms and tenses thereof) are used herein to be open ended terms. Thus, whenever a claim employs any form of “include” or “comprise” (e.g., comprises, includes, comprising, including, having, etc.) as a preamble or within a claim recitation of any kind, it is to be understood that additional elements, terms, etc., may be present without falling outside the scope of the corresponding claim or recitation. As used herein, when the phrase “at least” is used as the transition term in, for example, a preamble of a claim, it is open-ended in the same manner as the term “comprising” and “including” are open ended. The term “and/or” when used, for example, in a form such as A, B, and/or C refers to any combination or subset of A, B, C such as (1) A alone, (2) B alone, (3) C alone, (4) A with B, (5) A with C, (6) B with C, or (7) A with B and with C. As used herein in the context of describing structures, components, items, objects and/or things, the phrase “at least one of A and B” is intended to refer to implementations including any of (1) at least one A, (2) at least one B, or (3) at least one A and at least one B. Similarly, as used herein in the context of describing structures, components, items, objects and/or things, the phrase “at least one of A or B” is intended to refer to implementations including any of (1) at least one A, (2) at least one B, or (3) at least one A and at least one B. As used herein in the context of describing the performance or execution of processes, instructions, actions, activities, etc., the phrase “at least one of A and B” is intended to refer to implementations including any of (1) at least one A, (2) at least one B, or (3) at least one A and at least one B. Similarly, as used herein in the context of describing the performance or execution of processes, instructions, actions, activities, etc., the phrase “at least one of A or B” is intended to refer to implementations including any of (1) at least one A, (2) at least one B, or (3) at least one A and at least one B.

As used herein, singular references (e.g., “a”, “an”, “first”, “second”, etc.) do not exclude a plurality. The term “a” or “an” object, as used herein, refers to one or more of that object. The terms “a” (or “an”), “one or more”, and “at least one” are used interchangeably herein. Furthermore, although individually listed, a plurality of means, elements, or actions may be implemented by, e.g., the same entity or object. Additionally, although individual features may be included in different examples or claims, these may possibly be combined, and the inclusion in different examples or claims does not imply that a combination of features is not feasible and/or advantageous.

As used herein, unless otherwise stated, the term “above” describes the relationship of two parts relative to Earth. A first part is above a second part, if the second part has at least one part between Earth and the first part. Likewise, as used herein, a first part is “below” a second part when the first part is closer to the Earth than the second part. As noted above, a first part can be above or below a second part with one or more of: other parts therebetween, without other parts therebetween, with the first and second parts touching, or without the first and second parts being in direct contact with one another.

Notwithstanding the foregoing, in the case of referencing a semiconductor component (e.g., a transistor), a semiconductor die containing a semiconductor component, and/or an integrated circuit (IC) package containing a semiconductor die during fabrication or manufacturing, “above” is not with reference to Earth, but instead is with reference to an underlying substrate on which relevant components are fabricated, assembled, mounted, supported, or otherwise provided. Thus, as used herein and unless otherwise stated or implied from the context, a first component within a semiconductor die (e.g., a transistor or other semiconductor component) is “above” a second component within the semiconductor die when the first component is farther away from a substrate (e.g., a semiconductor wafer) during fabrication/manufacturing than the second component on which the two components are fabricated or otherwise provided. Similarly, unless otherwise stated or implied from the context, a first component within an IC package (e.g., a semiconductor die) is “above” a second component within the IC package during fabrication when the first component is farther away from a printed circuit board (PCB) to which the IC package is to be mounted or attached. It is to be understood that semiconductor components are often used in orientation different than their orientation during fabrication. Thus, when referring to a semiconductor component (e.g., a transistor), a semiconductor die containing a semiconductor component, and/or an integrated circuit (IC) package containing a semiconductor die during use, the definition of “above” in the preceding paragraph (i.e., the term “above” describes the relationship of two parts relative to Earth) will likely govern based on the usage context.

As used in this patent, stating that any part (e.g., a layer, film, area, region, or plate) is in any way on (e.g., positioned on, located on, disposed on, or formed on, etc.) another part, indicates that the referenced part is either in contact with the other part, or that the referenced part is above the other part with one or more intermediate part(s) located therebetween.

As used herein, connection references (e.g., attached, coupled, connected, and joined) may include intermediate members between the elements referenced by the connection reference and/or relative movement between those elements unless otherwise indicated. As such, connection references do not necessarily infer that two elements are directly connected and/or in fixed relation to each other. As used herein, stating that any part is in “contact” with another part is defined to mean that there is no intermediate part between the two parts.

Unless specifically stated otherwise, descriptors such as “first,” “second,” “third,” etc., are used herein without imputing or otherwise indicating any meaning of priority, physical order, arrangement in a list, and/or ordering in any way, but are merely used as labels and/or arbitrary names to distinguish elements for ease of understanding the disclosed examples. In some examples, the descriptor “first” may be used to refer to an element in the detailed description, while the same element may be referred to in a claim with a different descriptor such as “second” or “third.” In such instances, it should be understood that such descriptors are used merely for identifying those elements distinctly within the context of the discussion (e.g., within a claim) in which the elements might, for example, otherwise share a same name.

As used herein, “approximately” and “about” modify their subjects/values to recognize the potential presence of variations that occur in real world applications. For example, “approximately” and “about” may modify dimensions that may not be exact due to manufacturing tolerances and/or other real world imperfections as will be understood by persons of ordinary skill in the art. For example, “approximately” and “about” may indicate such dimensions may be within a tolerance range of +/−10% unless otherwise specified herein.

As used herein, the phrase “in communication,” including variations thereof, encompasses direct communication and/or indirect communication through one or more intermediary components, and does not require direct physical (e.g., wired) communication and/or constant communication, but rather additionally includes selective communication at periodic intervals, scheduled intervals, aperiodic intervals, and/or one-time events.

As used herein, “programmable circuitry” is defined to include (i) one or more special purpose electrical circuits (e.g., an application specific circuit (ASIC)) structured to perform specific operation(s) and including one or more semiconductor-based logic devices (e.g., electrical hardware implemented by one or more transistors), and/or (ii) one or more general purpose semiconductor-based electrical circuits programmable with instructions to perform specific functions(s) and/or operation(s) and including one or more semiconductor-based logic devices (e.g., electrical hardware implemented by one or more transistors). Examples of programmable circuitry include programmable microprocessors such as Central Processor Units (CPUs) that may execute first instructions to perform one or more operations and/or functions, Field Programmable Gate Arrays (FPGAs) that may be programmed with second instructions to cause configuration and/or structuring of the FPGAs to instantiate one or more operations and/or functions corresponding to the first instructions, Graphics Processor Units (GPUs) that may execute first instructions to perform one or more operations and/or functions, Digital Signal Processors (DSPs) that may execute first instructions to perform one or more operations and/or functions, XPUs, Network Processing Units (NPUs) one or more microcontrollers that may execute first instructions to perform one or more operations and/or functions and/or integrated circuits such as Application Specific Integrated Circuits (ASICs). For example, an XPU may be implemented by a heterogeneous computing system including multiple types of programmable circuitry (e.g., one or more FPGAs, one or more CPUs, one or more GPUs, one or more NPUs, one or more DSPs, etc., and/or any combination(s) thereof), and orchestration technology (e.g., application programming interface(s) (API(s)) that may assign computing task(s) to whichever one(s) of the multiple types of programmable circuitry is/are suited and available to perform the computing task(s).

As used herein integrated circuit/circuitry is defined as one or more semiconductor packages containing one or more circuit elements such as transistors, capacitors, inductors, resistors, current paths, diodes, etc. For example an integrated circuit may be implemented as one or more of an ASIC, an FPGA, a chip, a microchip, programmable circuitry, a semiconductor substrate coupling multiple circuit elements, a system on chip (SoC), etc.

From the foregoing, it will be appreciated that metal oxide resist layers, semiconductor fabrication methods, and devices made thereby have been disclosed herein. In some examples, the metal oxide resist layers include bismuth-phosphorus compounds and have increased stability when compared to prior photolithography resist layers. Example bismuth-phosphorus compounds disclosed herein have high photosensitivity when compared to prior resist layers and are suitable for use with EUV photolithography. Examples disclosed herein enable the deposition of such stable photo-sensitive metal oxide resist layer via any of a variety of deposition techniques, including atomic layer deposition, chemical vapor deposition, and spin-on deposition. Examples disclosed herein enable EUV photolithography tools to provide high-resolution, uniform, and high-speed patterning. The higher speed and lower power requirements enabled by the MOR materials disclosed herein reduces the manufacturing cost (e.g., lower power requirements, lower material requirements, etc.) and processing time required to perform photolithography and, thus, to fabricate semiconductor devices such as integrated circuits.

Further examples and combinations thereof include the following:
Example 1 includes a method of fabricating a semiconductor device, the method comprising depositing a metal oxide resist layer on a base material by applying a precursor including bismuth, the metal oxide resist layer including a bismuth phosphate compound, and patterning the metal oxide resist layer.
Example 2 includes the method of example 1, wherein the bismuth phosphate compound includes an aromatic group.
Example 3 includes the method of example 1, wherein the bismuth phosphate compound is a bismuth-14 cluster.
Example 4 includes the method of example 1, wherein the bismuth phosphate compound is a one-dimensional coordination polymer.
Example 5 includes the method of example 1, wherein the precursor is a bismuth alkoxide.
Example 6 includes the method of example 5, wherein the precursor is triphenylbismuthine.
Example 7 includes the method of example 1, wherein the precursor is a first precursor and the depositing of the metal oxide resist layer includes applying a second precursor including phosphorus.
Example 8 includes the method of example 7, wherein the second precursor includes a phosphate.
Example 9 includes the method of example 8, wherein the second precursor includes a one or more of alkyl groups.
Example 10 includes the method of example 7, wherein the second precursor includes a phosphonate.
Example 11 includes the method of example 7, wherein the depositing the metal oxide resist layer includes concurrently applying the first precursor and the second precursor via vapor deposition.
Example 12 includes the method of example 7, wherein the second precursor is silylated.
Example 13 includes the method of example 7, wherein the depositing of the metal oxide resist layer to the base material includes spinning coating a solution including the first precursor and the second precursor on the base material.
Example 14 includes the method of example 1, wherein the patterning of the metal oxide resist layer includes applying ultraviolet light having a wavelength of less than 20 nanometers.
Example 15 includes a semiconductor device comprising a semiconductor base layer, and a metal oxide resist layer on the semiconductor base layer, the metal oxide resist layer including a bismuth phosphate compound.
Example 16 includes the semiconductor device of example 15, wherein the bismuth phosphate compound includes a bismuth-14 cluster.
Example 17 includes the semiconductor device of example 15, wherein the bismuth phosphate compound includes a one-dimensional coordination polymer.
Example 18 includes the semiconductor device of example 15, wherein the metal oxide resist layer has a thickness of less than 20 nanometers.
Example 19 includes a spin-coating solution for depositing a metal oxide resist layer, the spin-coating solution including an organic solvent, and a bismuth-phosphorus cluster including a plurality of bismuth atoms, a plurality of phosphate moieties bonded to the plurality of bismuth atoms, and a plurality of aromatic groups, each of the plurality of aromatic groups bonded to a corresponding one of the phosphate moieties.
Example 20 includes the spin-coating solution of example 19, wherein the plurality of bismuth atoms includes fourteen bismuth atoms.

The following claims are hereby incorporated into this Detailed Description by this reference. Although certain example systems, apparatus, articles of manufacture, and methods have been disclosed herein, the scope of coverage of this patent is not limited thereto. On the contrary, this patent covers all systems, apparatus, articles of manufacture, and methods fairly falling within the scope of the claims of this patent.

What is claimed is:

1. A method of fabricating a semiconductor device, the method comprising:
depositing a metal oxide resist layer on a base material by applying a precursor including bismuth, the metal oxide resist layer including a bismuth phosphate compound; and
patterning the metal oxide resist layer.

2. The method of claim 1, wherein the bismuth phosphate compound includes an aromatic group.

3. The method of claim 1, wherein the bismuth phosphate compound is a bismuth-14 cluster.

4. The method of claim 1, wherein the bismuth phosphate compound is a one-dimensional coordination polymer.

5. The method of claim 1, wherein the precursor is a bismuth alkoxide.

6. The method of claim 5, wherein the precursor is triphenylbismuthine.

7. The method of claim 1, wherein the precursor is a first precursor and the depositing of the metal oxide resist layer includes applying a second precursor including phosphorus.

8. The method of claim 7, wherein the second precursor includes a phosphate.

9. The method of claim 8, wherein the second precursor includes a one or more of alkyl groups.

10. The method of claim 7, wherein the second precursor includes a phosphonate.

11. The method of claim 7, wherein the depositing the metal oxide resist layer includes concurrently applying the first precursor and the second precursor via vapor deposition.

12. The method of claim 7, wherein the second precursor is silylated.

13. The method of claim 7, wherein the depositing of the metal oxide resist layer to the base material includes spinning coating a solution including the first precursor and the second precursor on the base material.

14. The method of claim 1, wherein the patterning of the metal oxide resist layer includes applying ultraviolet light having a wavelength of less than 20 nanometers.

15. A semiconductor device comprising:
a semiconductor base layer; and
a metal oxide resist layer on the semiconductor base layer, the metal oxide resist layer including a bismuth phosphate compound.

16. The semiconductor device of claim 15, wherein the bismuth phosphate compound includes a bismuth-14 cluster.

17. The semiconductor device of claim 15, wherein the bismuth phosphate compound includes a one-dimensional coordination polymer.

18. The semiconductor device of claim 15, wherein the metal oxide resist layer has a thickness of less than 20 nanometers.

19. A spin-coating solution for depositing a metal oxide resist layer, the spin-coating solution including:
an organic solvent; and
a bismuth-phosphorus cluster including:
a plurality of bismuth atoms;
a plurality of phosphate moieties bonded to the plurality of bismuth atoms; and
a plurality of aromatic groups, each of the plurality of aromatic groups bonded to a corresponding one of the phosphate moieties.

20. The spin-coating solution of claim 19, wherein the plurality of bismuth atoms includes fourteen bismuth atoms.
